(19) United States
(12) Patent Application Publication
(10) Pub. No.: US 2026/0002259 A1
(43) Pub. Date: Jan. 1, 2026

(54) APPARATUS FOR DEPOSITING FOR ATOMIC LAYER

(71) Applicant: NCD CO., LTD., Daejeon (KR)

(72) Inventors: WOONG CHUL SHIN, Daejeon (KR); KYU-JEONG CHOI, Daejeon (KR); Cheol Hoon YANG, Daejeon (KR)

(21) Appl. No.: 18/880,271

(22) PCT Filed: Nov. 16, 2023
(86) PCT No.: PCT/KR2023/018423

§ 371 Date: Dec. 30, 2024

(51) Int. Cl. C23C 16/455; C23C 16/458; C23C 16/509

(52) U.S. Cl. CPC C23C 16/45546; C23C 16/45536; C23C 16/458; C23C 16/509

(57) ABSTRACT

Provided is a batch-type apparatus for atomic layer deposition for performing an atomic layer deposition process by generating a remote plasma between a showerhead and a cassette and bringing a process gas into a radical or ion state. The batch-type apparatus for atomic layer deposition includes a reaction chamber internally forming a predetermined reaction space isolated from an outside, gas supply means installed on one side of the reaction chamber and supplying the process gas in one direction inside the reaction chamber, gas discharge means installed on the other side facing the gas supply means in the reaction chamber and suctioning and discharging a gas supplied by the gas supply means and a gas inside the reaction chamber, a cassette disposed between the gas supply means and the gas discharge means inside the reaction chamber and mounting multiple substrates in parallel with each other in a separated state at a predetermined interval, and a plasma generation unit installed between the gas supply means and a front end of the cassette and generating a plasma in a front space of the cassette.

### TECHNICAL FIELD

The present disclosure relates to a batch-type apparatus for atomic layer deposition, and more specifically, relates to a batch-type apparatus for atomic layer deposition for performing an atomic layer deposition process by generating a remote plasma between a showerhead and a cassette and bringing a process gas into a radical or ion state.

### BACKGROUND ART

Atomic layer deposition (ALD) is similar to general chemical vapor deposition in that a chemical reaction between gas molecules is used. In the general chemical vapor deposition, multiple gas molecules are simultaneously injected into a chamber, and generated reaction products are deposited on a substrate. However, the atomic layer deposition (ALD) is different from the general chemical vapor deposition regarding the following points. A one source material containing a gas is injected into a chamber, and is chemically adsorbed onto a heated substrate. Thereafter, another source material containing a gas is injected into the chamber such that a product generated through a chemical reaction between the source materials is deposited on a surface of the substrate.

Currently, this atomic layer deposition (ALD) is widely used since there is an advantage in that step coverage characteristics are very excellent and a pure thin film having a low impurity content can be deposited.

Meanwhile, in apparatuses for atomic layer deposition, according to a batch type apparatus for atomic layer deposition in which deposition processes are simultaneously performed on multiple substrates to improve a throughput, multiple substrates are loaded into a reaction chamber in a state where the multiple substrates are separated at a predetermined interval in a cassette. In this state, a cycle including steps of providing a source gas, purging, providing a reaction gas, and purging is repeated multiple times.

However, in existing plasma apparatuses, as substrates increase in size and have larger areas, a process chamber and a showerhead also increase in size. As a result, since the substrates increase in size, there is a difference in gas injection amounts due to a difference in relative distances from a gas supply source, and unevenness in density of plasma generation becomes more severe, thereby causing a problem in that quality of a thin film deposited on the substrate deteriorates.

### DETAILED DESCRIPTION OF INVENTION

### Technical Problems

A technical aspect to be achieved by the present disclosure is to provide a batch-type apparatus for atomic layer deposition for performing an atomic layer deposition process by generating a remote plasma between a showerhead and a cassette and bringing a process gas into a radical or ion state.

### Technical Solution

According to the present disclosure for achieving the above-described technical aspect, a batch-type apparatus for atomic layer deposition includes a reaction chamber internally forming a predetermined reaction space isolated from an outside, gas supply means installed on one side of the reaction chamber and supplying a process gas in one direction inside the reaction chamber, gas discharge means installed on the other side of the reaction chamber facing the gas supply means and suctioning and discharging a gas supplied by the gas supply means and a gas inside the reaction chamber, a cassette disposed between the gas supply means and the gas discharge means inside the reaction chamber and mounting multiple substrates in parallel with each other in a separated state at a predetermined interval, and a plasma generation unit installed between the gas supply means and a front end of the cassette and generating a plasma in a front space of the cassette.

In the present disclosure, it is preferable that the plasma generation unit includes a gas distribution electrode installed between the source supply means and the front end of the cassette, transmitting the source gas supplied by the source supply means in the direction of the cassette, and to which plasma generation power is applied or grounded, and power supply means for grounding the source supply means when the plasma generation power is applied to the gas distribution electrode, and for grounding the gas distribution electrode when the plasma generation power is applied to the source supply means.

In addition, in the present disclosure, it is preferable that the gas distribution electrode has multiple rows of gas injection holes or gas injection slits formed to match positions of the multiple substrates mounted on the cassette.

In addition, in the present disclosure, it is preferable that the gas injection hole has a structure in which a large-diameter gas passage hole is formed by penetrating the gas distribution electrode in a direction of the source supply means, and a small-diameter gas passage hole having a smaller diameter than the large-diameter gas passage hole is formed by penetrating the gas distribution electrode in the direction of the cassette.

In addition, in the present disclosure, it is preferable that the gas injection slit has a structure in which gas passage slits are formed at a predetermined interval in the direction of the gas supply means, and small-diameter gas passage holes having a smaller diameter than the interval of the gas passage slits are formed in one row along the gas passage slits in the direction of the cassette.

In addition, in the present disclosure, it is preferable that the power supply means supplies the plasma generation power to the gas supply means and ground the gas distribution electrode.

In addition, in the present disclosure, it is preferable that the plasma generation unit includes a gas injection hole in which a large-diameter gas passage hole is formed by penetrating a showerhead panel of the gas supply means in a direction of the gas distribution electrode, and a small-diameter gas passage hole having a smaller diameter than the large-diameter gas passage hole is formed to communicate with the large-diameter gas passage hole by penetrating the showerhead panel of the gas supply means in a direction opposite to the gas distribution electrode.

In addition, in the present disclosure, it is preferable that the plasma generation unit includes a gas injection slit in which gas passage slits are formed at a predetermined interval by penetrating the showerhead panel of the gas supply means in the direction of the gas distribution electrode, and small-diameter gas passage holes having a smaller diameter than the gas passage slit interval are formed by penetrating the showerhead panel of the gas supply means in the direction opposite to the gas distribution electrode.

In addition, in the present disclosure, it is preferable that the plasma generation unit includes a power electrode installed in one side end of a space between the gas supply means and the cassette, and to which the plasma generation power is applied, a ground electrode installed at a position facing the power electrode, and grounded, and a power supply unit that applies the plasma generation power to the power electrode.

In addition, in the present disclosure, it is preferable that the plasma generation unit includes multiple power electrodes installed at a predetermined interval in a direction coinciding with a direction of the substrates mounted on the cassette in a space between the gas supply means and the cassette, and to which the plasma generation power is applied, multiple ground electrodes installed at an interval from the power electrodes at every location between the multiple power electrodes, and grounded, and a power supply unit that applies the plasma generation power to the power electrodes.

In addition, in the batch-type apparatus for atomic layer deposition according to the present disclosure, it is preferable that the power electrode and the ground electrode are disposed at positions that coincide with a substrate mounting slit of the cassette.

In addition, in the present disclosure, it is preferable that the power electrode includes multiple electrode plates installed at a predetermined interval, and a connection portion connecting ends of the multiple electrode plates and connecting the multiple electrode plates and the power supply unit.

In addition, in the present disclosure, it is preferable that the ground electrode includes multiple ground plates installed at a predetermined interval, and a ground connection portion connecting ends of the multiple ground plates and connecting the multiple ground electrodes to the power supply unit.

In addition, in the batch-type apparatus for atomic layer deposition according to the present disclosure, it is preferable that the power electrode and the ground electrode have an overall plate shape to divide a space between the gas supply means and the cassette into a gas supply space which coincides with a substrate mounting space inside the cassette.

In addition, in the present disclosure, it is preferable that the plasma is an RF plasma, a CCP plasma, an ICP plasma, an ECR plasma, or a Pulse DC plasma. The articulated work robot device according to one embodiment of the present disclosure can minimize the rotation radius by folding the non-work articulated arm during the common axis rotation.

### BRIEF DESCRIPTION OF THE DRAWING

FIG. 1 is a cross-sectional view schematically illustrating a structure of a batch-type apparatus for atomic layer deposition according to one embodiment of the present disclosure.

FIG. 2 is a view illustrating a structure of a gas distribution plate and a gas injection hole according to one embodiment of the present disclosure.

FIG. 3 is a view illustrating a structure of a gas distribution plate and a gas injection slit according to another embodiment of the present disclosure.

FIG. 4 is a cross-sectional view and a plan view illustrating a structure of a gas distribution plate and a gas injection hole according to still another embodiment of the present disclosure.

FIG. 5 is a cross-sectional view and a plan view illustrating a structure of a gas distribution plate and a gas injection slit according to still another embodiment of the present disclosure.

FIG. 6 is a cross-sectional view and a plan view illustrating a structure of gas supply means and a gas injection hole according to still another embodiment of the present disclosure.

FIG. 7 is a cross-sectional view and a plan view illustrating a structure of gas supply means and a gas injection slit according to still another embodiment of the present disclosure.

FIG. 8 is a cross-sectional view schematically illustrating a structure of a batch-type apparatus for atomic layer deposition according to another embodiment of the present disclosure.

FIG. 9 is a cross-sectional view schematically illustrating a structure of a batch-type apparatus for atomic layer deposition according to still another embodiment of the present disclosure.

FIG. 10 is a cross-sectional view illustrating a structure of a power electrode and a ground electrode according to still another embodiment of the present disclosure.

### BEST MODE FOR CARRYING OUT THE INVENTION

Hereinafter, specific embodiments of the present disclosure will be described in detail with reference to the accompanying drawings.

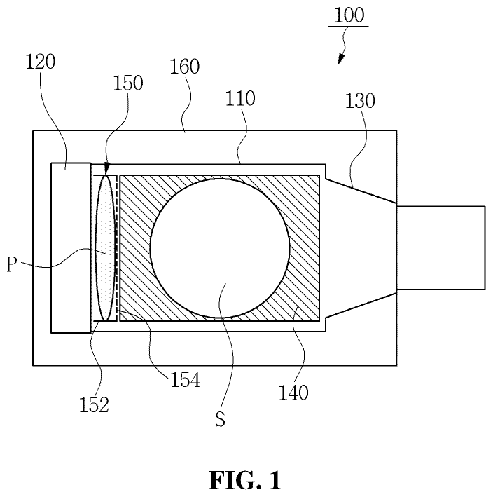

As illustrated in FIG. 1, a batch-type apparatus for atomic layer deposition (100) according to the present embodiment may be configured to include a reaction chamber (110), gas supply means (120), gas discharge means (130), a cassette (140), and a plasma generation unit (150).

First, the reaction chamber (110) is a component that internally forms a predetermined reaction space isolated from an outside. In particular, in the present embodiment, the reaction chamber (110) has a structure which may isolate the reaction space from an outside space to create a vacuum state with a very low pressure. In order to secure stable process conditions of the reaction chamber (110), the reaction chamber (110) may further include an external chamber (160) as illustrated in FIG. 1.

Next, as illustrated in FIG. 1, the gas supply means (120) is a component installed on one side of the reaction chamber (110) and supplying a process gas in one direction inside the reaction chamber (110). That is, the gas supply means (120) supplies a process gas and a purge gas in a direction of the cassette (140) so that an atomic layer deposition process may be performed on multiple substrates mounted inside the reaction chamber (110).

Therefore, in the present embodiment, for example, in order to supply a uniform gas, the gas supply means (120) may have a showerhead panel structure in which multiple gas injection holes are formed.

Next, as illustrated in FIG. 1, the gas discharge means (130) is a component installed on the other side facing the gas supply means (120) in the reaction chamber (110), suctioning a gas supplied by the gas supply means (120) and a gas inside the reaction chamber (110), and discharging the gas to the outside. That is, the gas discharge means (130) strongly suctions the gas from a side opposite to the gas supply means (120) so that a uniform gas flow is formed in the reaction space inside the reaction chamber (110), suctions the gas passing through the cassette mounting space, and discharges the gas to the outside.

Next, as illustrated in FIG. 1, the cassette (140) is a component disposed between the gas supply means (120) and the gas discharge means (130) inside the reaction chamber (110) and mounting multiple substrates (S) in parallel with each other in a separated state at a predetermined interval. Therefore, the multiple substrates (S) are mounted in parallel with each other on the cassette (140), and an interval between the respective substrates is maintained at an interval suitable for performing an atomic layer deposition process.

Next, as illustrated in FIG. 1, the plasma generation unit (150) is a component installed between the gas supply means (120) and the front end of the cassette (140) and generating the plasma in a front space of the cassette (140). That is, the plasma generation unit (150) generates a remote plasma in a space between the gas supply means (120) and a front end of the cassette (140). In this manner, an atomic layer deposition process is performed on the substrate (S) in such a manner that the process gas to be supplied in a direction of the cassette (140) by the gas supply means (120) is changed into a radical or ion state.

For this purpose, in the present embodiment, the plasma generation unit (150) may include a gas distribution electrode (152) and power supply means (not illustrated in the drawing) as specifically illustrated in FIG. 1. First, the gas distribution electrode (152) is a component installed between the gas supply means (120) and the front end of the cassette (140), transmitting the gas supplied by the gas supply means (120) in the direction of the cassette, and to which high-frequency power for plasma generation is applied.

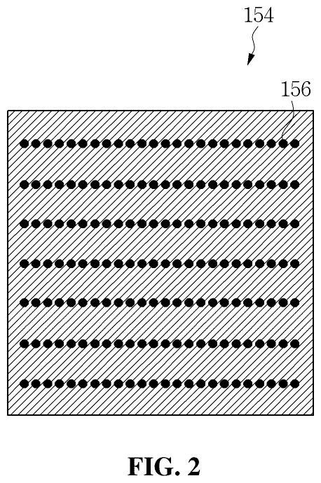

Therefore, as illustrated in FIG. 2, the gas distribution electrode (152) is provided with a gas distribution plate (154) in which multiple rows of gas injection holes (156) are formed, and the gas injected by the gas supply means (120) uniformly moves in a direction of the cassette (140). In this case, as illustrated in FIG. 2, it is preferable that the gas injection holes (156) have an arrangement that matches positions of multiple substrates (S) mounted on the cassette (140).

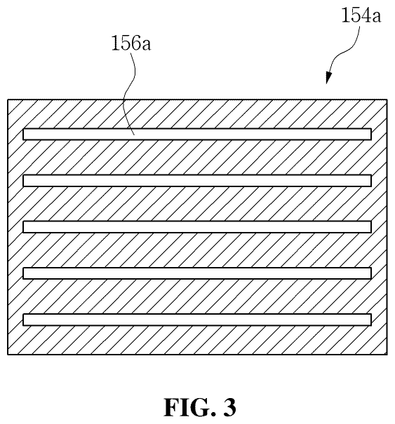

Meanwhile, as illustrated in FIG. 3, multiple rows of gas injection slits (156a) may be formed in the gas distribution plate (154a). The gas injection slits (156a) are formed as long gaps, and it is preferable that the multiple gas injection slits (156a) have an arrangement that matches the positions of the multiple substrates (S) mounted on the cassette (140).

The power supply means (not illustrated in the drawing) is a component applying the plasma generation power to the gas distribution electrode (152) and grounding the gas supply means (120). That is, the power supply means is installed outside the reaction chamber (110), applies high-frequency power for plasma generation to the gas distribution electrode (152), and grounds the gas supply means (120) to create a plasma generation environment.

Meanwhile, in the present embodiment, the power supply means may adjust the plasma generation environment by applying the plasma generation power to the gas supply means (120) and grounding the gas distribution electrode (152).

### Embodiment 2

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas supply means, the gas discharge means, and the cassette are substantially the same as those of Embodiment 1, repeated description thereof will be omitted.

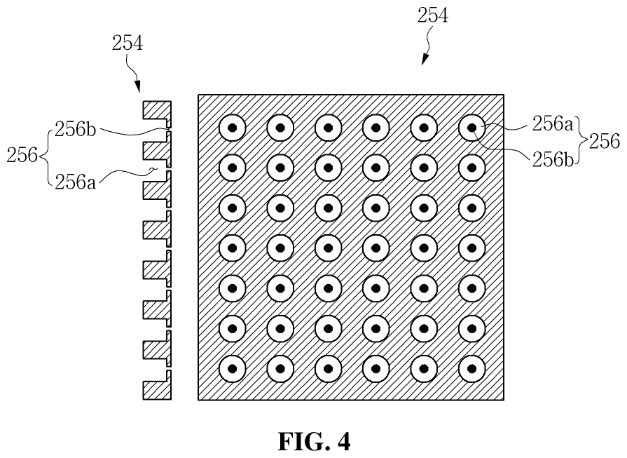

However, in the batch-type apparatus for atomic layer deposition according to the present embodiment, a structure of the plasma generation unit is different from that of Embodiment 1. In particular, since a structure of the gas injection hole (256) is different, the structure of the gas injection hole (256) will be described in detail. Specifically, as illustrated in FIG. 4, the gas injection hole (256) in the present embodiment is implemented with the following structure. A large-diameter gas passage hole (256a) is formed by penetrating the gas distribution plate (254) in a direction of the gas supply means, and a small-diameter gas passage hole (256b) having a smaller diameter than the large-diameter gas passage hole (256a) is formed by penetrating the gas distribution plate (254) in a direction of the cassette.

According to the gas injection hole (256) having this structure, there is an advantage in that a higher density plasma is formed by each of the gas injection holes.

### Embodiment 3

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas supply means, the gas discharge means, and the cassette are substantially the same as those of Embodiment 1, repeated description thereof will be omitted.

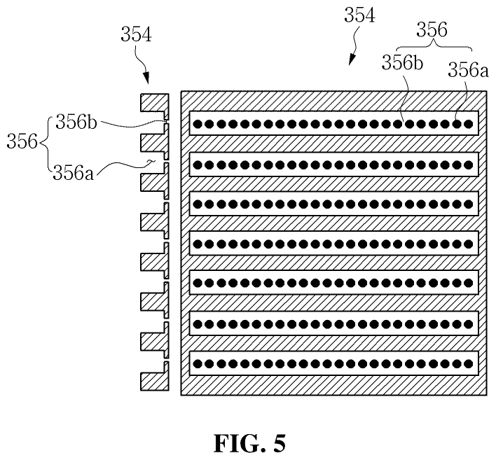

However, in the batch-type apparatus for atomic layer deposition according to the present embodiment, a structure of the plasma generation unit is different from that of Embodiment 1, and in particular, a structure of the gas injection slit (356) is different. Specifically, as illustrated in FIG. 5, the gas injection slit (356) in the present embodiment is implemented with the following structure. Gas passage slits (356a) are formed at a predetermined interval in the gas distribution plate (354) in a direction of the gas supply means, and small-diameter gas passage holes (356b) having a smaller diameter than a width of the gas passage slit (356a) are formed in one row along the gas passage slit (356a) in a direction of the cassette.

As in the gas injection hole (256) of Embodiment 2, the gas injection slit (356) having this structure has an advantage in that a higher density plasma is formed by each of the gas injection slits (356a) and each of the gas passage holes (356b).

### Embodiment 4

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas discharge means, and the cassette are substantially the same as those of Embodiment 1, repeated description thereof will be omitted.

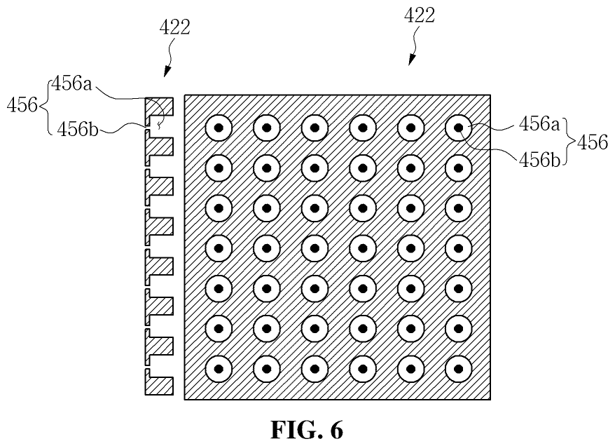

However, in the batch-type apparatus for atomic layer deposition according to the present embodiment, structures of the gas supply means and the plasma generation unit are different from those of Embodiment 1, and in particular, a structure of the gas injection hole (456) is different. Specifically, as illustrated in FIG. 6, the gas injection hole (456) in the present embodiment is implemented with the following structure. A large-diameter gas passage hole (456a) is formed by penetrating the showerhead panel (422) of the gas supply means in a direction of the gas distribution electrode, and a small-diameter gas passage hole (456b) having a smaller diameter than the large-diameter gas passage hole (456a) is formed to communicate with the large-diameter gas passage hole (456a) by penetrating the showerhead panel (422) of the gas supply means in a direction opposite to the gas distribution electrode.

As in the gas injection hole (256) of Embodiment 2, the gas injection hole (456) having this structure has an advantage in that a higher density plasma is formed by each of the gas injection holes.

### Embodiment 5

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas discharge means, and the cassette are substantially the same as those of Embodiment 1, repeated description thereof will be omitted.

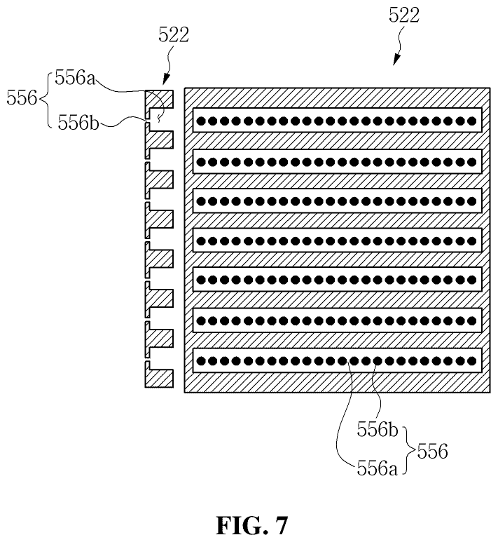

However, in the batch-type apparatus for atomic layer deposition according to the present embodiment, structures of the gas supply means and the plasma generation unit are different from those of Embodiment 1, and in particular, a structure of the gas injection slit (556) is different. Specifically, as illustrated in FIG. 7, the gas injection slit (556) in the present embodiment is implemented with the following structure. A showerhead panel (522) of the gas supply means is engraved in a direction of the gas distribution electrode to form gas passage slits (556a) at a predetermined interval, and small-diameter gas passage holes (556b) having a smaller diameter than an interval of the gas passage slits are formed in one row along the gas passage slits in a direction opposite to the gas distribution electrode.

As in the gas injection hole (256) of Embodiment 2, the gas injection slit (556) having this structure has an advantage in that a higher density plasma is formed by each of the gas injection slits and each of the gas passage holes.

### Embodiment 6

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas supply means, the gas discharge means, and the cassette are substantially the same as those of Embodiment 1, repeated description thereof will be omitted.

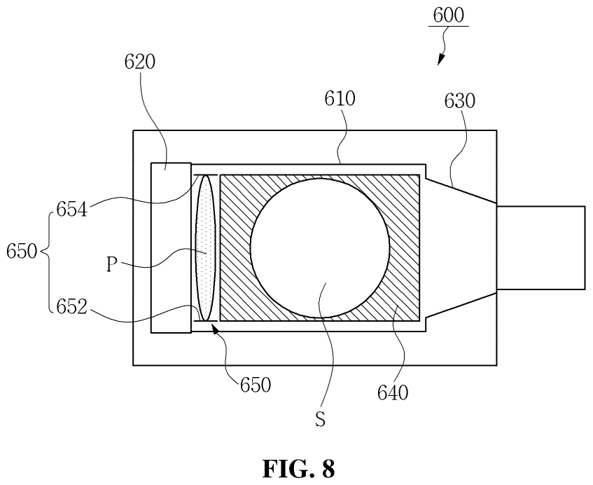

However, in the batch-type apparatus for atomic layer deposition according to the present embodiment, a structure of the plasma generation unit is different from that of Embodiment 1, and specifically, as illustrated in FIG. 8, the batch-type apparatus for atomic layer deposition according to the present embodiment may be configured to include a power electrode (652), a ground electrode (654), and a power supply unit (not illustrated in the drawing).

First, the power electrode (652) is a component installed in one side end of a space between the gas supply means (620) and the cassette (640), and to which high-frequency power for plasma generation is applied. As illustrated in FIG. 8, the ground electrode (654) is a component installed at a position facing the power electrode (652), and grounded. Finally, the power supply unit applies high-frequency power for plasma generation to the power electrode (652). In this manner, the plasma is generated in a space between the power electrode (652) and the ground electrode (654).

### Embodiment 7

As in the configuration of Embodiment 1, the batch-type apparatus for atomic layer deposition according to the present embodiment may also be configured to include the reaction chamber, the gas supply means, the gas discharge means, the cassette, and the plasma generation unit. Since the reaction chamber, the gas supply means, the gas discharge means, and the cassette are substantially the same as those of Embodiment 1, repeated description thereof will be omitted.

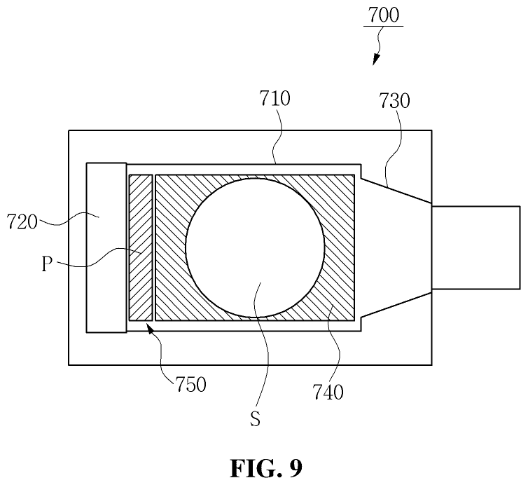

However, in the batch-type apparatus for atomic layer deposition according to the present embodiment, a structure of the plasma generation unit is different from that of Embodiment 1, and specifically, as illustrated in FIG. 9, the batch-type apparatus for atomic layer deposition according to the present embodiment may be configured to include a power electrode (752), a ground electrode (754), and a power supply unit (not illustrated in the drawing).

First, multiple power electrodes (752) are components installed at a predetermined interval in a space between the gas supply means (720) and the cassette (740) in a direction coinciding with the direction of the substrates (S) mounted on the cassette (740), and to which the plasma generation power is applied.

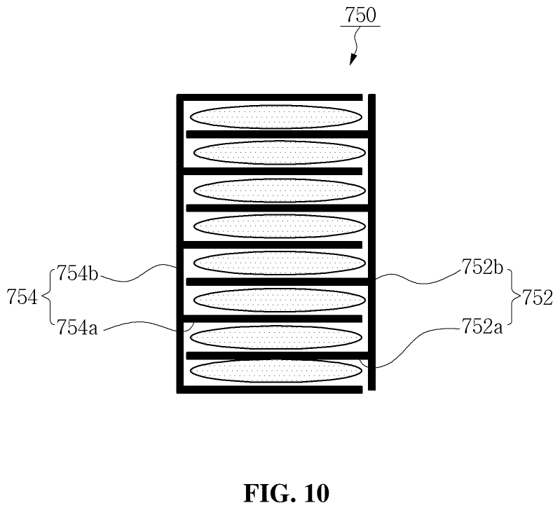

Here, specifically, as illustrated in FIG. 10, the power electrode (752) is configured to include multiple electrode plates (752a) and a connection portion (752b). The electrode plate (752a) is configured to include multiple conductive plates separated at a predetermined interval and installed in parallel with each other. The connection portion (752b) is a component connecting ends of the multiple electrode plates (752a) and connecting the multiple electrode plates (752a) and the power supply unit.

Next, as illustrated in FIG. 10, multiple ground electrodes (754) are components installed at an interval from the power electrode (752) at every location between the multiple power electrodes (752), and grounded. Specifically, the ground electrode (754) is configured to include multiple ground plates (754b) and a ground connection portion (754b). As a matter of course, the ground electrode (754) and the power electrode (752) are installed in an insulated state from each other.

First, as illustrated in FIG. 10, the multiple ground plates (754a) are installed at a predetermined interval, and are installed so that an interval between the ground plates (754a) coincides with an interval between the electrode plates (752a). Each of the ground plates (754a) is installed at the center of the adjacent electrode plates (752a). In addition, the ground connection portion (754b) is a component connecting ends of the multiple ground plates (754a) and connecting the multiple ground plates (754a) and the power supply unit.

Therefore, the intervals between the multiple ground plates (754a) and the electrode plates (752a) are maintained constant, and the multiple ground plates (754a) and the electrode plates (752a) divide the space between the gas supply means (720) and the cassette (740) into a gas supply space which coincides with the substrate mounting space inside the cassette (740).

Next, the power supply unit is a component applying the plasma generation power to the power electrode (752) and grounding the ground electrode (754).

### INDUSTRIAL APPLICABILITY

According to the present disclosure, a uniform atomic layer deposition process may be performed on multiple large-area substrates during a process of manufacturing semiconductors, solar cells, display panels, or the like. In particular, thin film properties are improved during deposition work, and thus, the present disclosure is applicable to semiconductor, solar cell, and display industries.

1. A batch-type apparatus for atomic layer deposition, comprising:
a reaction chamber internally forming a predetermined reaction space isolated from an outside;
a cassette disposed on one side inside the reaction chamber and mounting multiple substrates in parallel with each other in a separated state at a predetermined interval;
source supply means installed on the other side of the reaction chamber and supplying a source gas in a direction of the cassette;
a plasma generation unit installed between the source supply means and a front end of the cassette and generating a plasma in a front space of the cassette;
precursor supply means installed on a side wall of the reaction chamber and supplying a precursor gas to a space between the plasma generation unit and the cassette; and
gas discharge means installed on the other side facing the source supply means in the reaction chamber and suctioning and discharging a gas supplied by the source supply means and the precursor supply means and a gas inside the reaction chamber.

2. The batch-type apparatus for atomic layer deposition of claim 1, wherein the plasma generation unit includes a gas distribution electrode installed between the source supply means and the front end of the cassette, transmitting the source gas supplied by the source supply means in the direction of the cassette, and to which plasma generation power is applied or grounded, and power supply means for grounding the source supply means when the plasma generation power is applied to the gas distribution electrode, and for grounding the gas distribution electrode when the plasma generation power is applied to the source supply means.

3. The batch-type apparatus for atomic layer deposition of claim 2, wherein the gas distribution electrode has multiple rows of gas injection holes or gas injection slits formed to match positions of the multiple substrates mounted on the cassette.

4. The batch-type apparatus for atomic layer deposition of claim 3, wherein the gas injection hole has a structure in which a large-diameter gas passage hole is formed by penetrating the gas distribution electrode in a direction of the source supply means, and a small-diameter gas passage hole having a smaller diameter than the large-diameter gas passage hole is formed by penetrating the gas distribution electrode in the direction of the cassette.

5. The batch-type apparatus for atomic layer deposition of claim 3, wherein the gas injection slit has a structure in which gas passage slits are formed at a predetermined interval in the direction of the gas supply means, and small-diameter gas passage holes having a smaller diameter than the interval of the gas passage slits are formed in one row along the gas passage slits in the direction of the cassette.

6. The batch-type apparatus for atomic layer deposition of claim 1, wherein the plasma generation unit includes a power electrode installed in one side end of a space between the source supply means and the cassette, and to which the plasma generation power is applied, a ground electrode installed at a position facing the power electrode, and grounded, and a power supply unit that applies the plasma generation power to the power electrode.

7. The batch-type apparatus for atomic layer deposition of claim 1, wherein the plasma generation unit includes multiple power electrodes installed at a predetermined interval in a direction coinciding with a direction of the substrates mounted on the cassette in a space between the source supply means and the cassette, and to which the plasma generation power is applied, multiple ground electrodes installed at an interval from the power electrodes at every location between the multiple power electrodes, and grounded, and a power supply unit that applies the plasma generation power to the power electrodes.
